(19) United States
(12) Patent Application Publication
(10) Pub. No.: US 2004/0157747 A1
(43) Pub. Date: Aug. 12, 2004

(54) Biaxially textured single buffer layer for superconductive articles

(75) Inventors: Xin Chen, Houston, TX (US); Naijuan Wu, Pearland, TX (US); Alex Ignatiev, Houston, TX (US); Yimin Chen, Bridgewater, NJ (US)

Correspondence Address: ROBERT W. STROZIER, SUITE 930, 2925 BRIARPARK DRIVE, HOUSTON, TX, 77042, US

(73) Assignee: THE UNIVERSITY OF HOUSTON SYSTEM

(21) Appl. No.: 10/364,908

(22) Filed: Feb. 10, 2003

(51) Int. Cl. B32B 1/00; H01F 6/00; H01B 12/00; H01L 39/00

(52) U.S. Cl. 505/238

(57) ABSTRACT

A thick atomically ordered single buffer layer for use in the integration of high temperature superconductor films with metallic substrates is disclosed. The buffer layer is a doped cerium oxide (CeO₂) material, where the doping reduces layer cracking through the modification of thermal expansion coefficient and film strain properties, while adjusting chemical properties and lattice parameters to better match those of the substrate and HTS layer.

### BACKGROUND OF THE INVENTION

1. Field of the Invention

The present invention relates to a single biaxially textured buffer layer or intermediate layer.

More particularly, the present invention relates to a single biaxially textured buffer layer or intermediate layer including a doped oxide layer, which separates a conductive layer, e.g., a superconducting layer from a substrate.

2. Description of the Related Art

High Tc superconducting (HTS) wires and tapes are currently being developed for many important applications. Within this arena so-called second generation HTS wire is based on thin film YBa₂Cu₃O_{7-δ} (YBCO) deposited on a flexible metallic substrate because of its high critical current density and its high critical field. However, because of weak link problems, the YBCO film is preferred to be single crystalline or atomically ordered for maximum critical current. Atomically ordered YBCO films can be obtained by growth of YBCO on an atomically ordered substrate. One specific type of atomically ordered substrate for the atomically ordered YBCO growth is roll-textured nickel or nickel alloys, as described, for example in U.S. Pat. No. 6,106,615 and U.S. Pat. No. 5,898,020, incorporated herein by reference. However, nickel diffuses into the YBCO film and destroys its superconducting properties. Therefore, buffer layers are required to be grown onto the Ni (or other metallic substrates) before superconducting YBCO can be grown.

It is important to note that the buffer layers have to be atomically ordered to accommodate atomically ordered YBCO growth. These can be developed either by growth of atomically ordered buffer layers on atomically ordered metallic substrates, or by the development of atomically ordered buffer layers on non-atomically ordered substrates by techniques such as ion beam assisted deposition (IBAD) as described in Y. Iijima et al. “Structural and Transport-Properties of Biaxially Aligned YBa₂Cu₃O_{7-δ}, Films on Polycrystalline Ni-Based Alloy With Ion-Beam-Modified Buffer Layers” 74(3) J. Appl. Phys 1905-1911 (1993), XD. Wu et al. “Preparation of High-Quality YBa2Cu307-o Thick-Films on Flexible Ni-Based Alloy Substrates With Textured Buffer Layers” 5(2) IEEE. T. Appl. Supercon. 2001-2006 (1995) and in U.S. Pat. No. 5,432,151, incorporated herein by reference, or inclined substrate deposition (ISD) as described in K. Hasegawa et al., “Biaxially aligned YBCO film tapes fabricated by all pulsed laser deposition” 4(10-11) Applied Superconductivity 487-493 (1996).

The deposition of buffer layers on atomically ordered substrates can be accommodated by a number of thin film growth techniques including pulsed laser deposition (as described in C. H. Hur et al., “Fabrication of YBa₂Cu₃O₇₋ₓ superconducting film with CeO₂/BaTiO double buffer layer” 398-399 Thin Solid Films 444-447 (2001)), electron beam evaporation and r-f sputtering (as described in F. A. List et at., “High J(c) YBCO films on biaxially textured Ni with oxide buffer layers deposited using electron beam evaporation and sputtering” 302(1) Physica C 87-92 (1998)), MOCVD (as described in A. Ignatiev et al. “Photo-assisted MOCVD fabrication of YBCO thick films and buffer layers on flexible metal substrates for wire applications”, 12(29-31) International Journal of Modern Physics B 3162-3173 (1998)), and sol-gel methods (as described in M. Jin et al., “Biaxial texturing of Cu sheets and fabrication of ZrO₂ buffer layer for YBCO HTS films” C 334(3-4) PHYSICA 243-248 (2000), E. Celik et al., “CeO₂ buffer layers for YBCO: Growth and processing via sol-gel technique” 9(2) IEEE Transactions on Applied Superconductivity 2264-2267 Part 2 (1999), and in U.S. Pat. No. 6,077,344). Yttria stabilized zirconia (YSZ) is an important buffer material for YBCO integration with metallic substrates, however, as described in U.S. Pat. No. 5,972,847, it is hard to develop directly on the nickel substrates due to the high temperatures required for the formation of atomic order and resultant oxidation of nickel. A lower growth temperature buffer layer between YSZ and the substrate is therefore preferred. CeO₂ is such a buffer layer, however, when used as buffer layer for YBCO thin films on textured Ni, CeO₂ usually develops cracks when its thickness reaches several tens of nanometers. As a result, additional buffer layers such as YZS, are needed. As a result, multi-layer buffer systems (such as the aforementioned CeO₂/YSZ/CeO₂ buffer layers) are used. Such multi-layer buffers increase process difficulty and production costs.

It has long been desired to grow biaxially oriented oxide buffer layers other than CeO₂ directly on textured substrates, and also to have a single buffer layer on textured substrates as described in U.S. Pat. No. 6,150,034 and in U.S. Pat. No. 6,156,376.

After years of research, there are have been some breakthroughs in the single buffer layer development. RE₂O₃ type oxides such as Y₂O₃ and Yb₂O₃ have been deposited on roll-textured nickel foils and are suggested as possible single buffer layer materials as described in U.S. Pat. No. 6,150,034.

Besides RE₂O₃, a perovskite-structured oxide BaTiO₃ has been tried as a single buffer layer, but the result is not as good as a double layer (C. H. Hur et al., “Fabrication of YBa₂Cu₃O₇₋ₓ superconducting film with CeO₂/BaTiO double buffer layer” 398-399 Thin Solid Films 444-447 (2001)). Reported in the same year, a perovskite-structured doped conductive oxide La_{0.7}Sr_{0.3}Mn_{O3} has been deposited with rf-magnetron sputtering and has successfully been used as a single buffer layer for the development of YBCO coated conductors (T. Aytug et al., “La_{0.7}Sr_{0.3}MnO₃: A single, conductive-oxide buffer layer for the development of YBa₂Cu₃O_{7-d} coated conductors” 79(14) Appl. Phys. Lett. 2205-2207 (2001)).

The fluorite-structured oxides are traditional buffer materials for YBCO on biaxially textured metal substrates. They are easy to be integrated with nickel and YBCO, and peopled are more experienced in depositing these materials for the YBCO tape and wire applications. It will be important to develop a single fluorite-structured oxide buffer for superconducting YBCO applications.

The inventors first attempt at developing new fluorite-structured buffer materials was reported in 1999 (N. J. Wu et al., “Epitaxial Layers and Bilayers of Cerium Oxide and Yttria-Stabilized Zirconia on Roll-Textured Nickel Foil by Laser Ablation and MOCVD”, 6th International Workshop on Oxide Electronics, College Park, Md., Dec. 6-7, 1999), in which the inventors reported the deposition of Sm doped CeO₂ as a buffer layer for YBCO films for metallic substrates applications.

Other researchers have used Gd-doped CeO₂ (CGO) as a buffer layer for YBCO to study grain boundaries in YBCO films (K. Thiele et al., “Grain boundaries in YBa₂Cu₃O_{7-δ} films grown on bicrystalline Ni substrates” 355 Physica C 203-210 (2001)). The critical thickness of crack formation for the CGO seems higher that CeO₂; however, the CGO films sometimes contains 45 degree twins and were deposited only on single crystalline nickel and bicrystalline nickel films. It has not been made on roll-textured nickel foils.

In another approach, YSZ is reported to have been deposited as a single buffer layer for YBCO, which is actually a single deposition step developed YSZ/NiO double layer (C. Park et al., “Epitaxial yttria-stabilized zirconia on biaxially-textured (001) Ni for YBCO coated conductor” 34-348 Physica C 2481-2482 (2000)).

Thus, there is a need in the art for buffer layers capable of integrating YBCO films or similar films into single buffer systems devices, especially buffer layers having a fluorite-structure.

### SUMMARY OF THE INVENTION

The present invention provides a new biaxially textured, single buffer layer for use integrating high Tc superconducting (HTS) films with metallic substrates. The new buffer layer is a doped CeO₂ based oxide film, which improves property matching between a high Tc supconductor and a metallic substrate, where the properties include a thermal expansion coefficient and lattice parameters.

The present invention also provides an apparatus including a metallic substrate, a biaxially textured, buffer layer and a high Tc superconducting (HTS) film.

The present invention also provides an apparatus including a metallic substrate, at least two buffer layers, at least one of the buffer layers comprising a biaxially textured, doped CeO₂ based oxide, buffer layer and a high Tc superconducting (HTS) film.

The present invention also provides a method for making an apparatus of this invention including depositing a doped CeO₂ based oxide, biaxially textured, buffer layer on a metallic substrate followed by forming an HTS layer on top of the buffer layer. The depositing step can be any process designed to form thin films including pulsed laser deposition (PLD), sputtering, physical vapor deposition, metal organic chemical vapor deposition (MOCVD), metal organic deposition (MOD) or mixtures or combinations thereof.

The present invention also provides a method for atomic ordering of a buffer layer on a substrate, where the method includes epitaxially growing a buffer layer on an atomically ordered metallic substrate, where the growing step can be pulsed laser deposition (PLD), sputtering, physical vapor deposition, metal organic chemical vapor deposition (MOCVD), metal organic deposition (MOD) or mixtures or combinations thereof.

### DESCRIPTION OF THE DRAWINGS

The invention can be better understood with reference to the following detailed description together with the appended illustrative drawings in which like elements are numbered the same:

FIG. 1 depicts a schematic of a single buffer layer used for integration of high temperature superconducting films to metallic substrates;

FIG. 2 depicts an SEM micrograph of an Sm-doped CeO₂ thin film grown by pulsed laser deposition on atomically ordered nickel;

FIG. 3 depicts an XRD pole figure and φ-scan of Sm-doped CeO₂ and YSZ thin films grown on atomically ordered nickel by PLD;

FIG. 4 depicts an SEM micrograph of the surface of YBCO/Sm—CeO₂/atomically ordered Ni sample;

FIG. 5 depicts an XRD θ-2θ scan for the YBCO/Sm—CeO₂/atomically ordered Ni sample;

FIG. 6 depicts an XRD pole figure and φ-scan of YBCO (103) reflection for YBCO grown on Sm—CeO₂/atomically ordered Ni;

FIG. 7 depicts an XRD pole figure and φ-scan of YBCO (103) reflection for YBCO grown on Sm—CeO₂/single crystalline Ni;

FIG. 8 depicts a J_{C} test for a YBCO film grown with PLD on Sm—CeO₂/single crystalline Ni at 77K and zero magnetic field;

FIG. 9 depicts an XRD pole figure and φ-scan of YBCO (103) for YBCO grown by MOCVD on Sm—CeO₂/atomically ordered Ni; and

FIG. 10 depicts an XRD pole figure and φ-scan of YSZ from a YSZ/Sm—CeO₂/atomically ordered Ni sample.

### DETAILED DESCRIPTION OF THE INVENTION

The inventors have found that a single buffer layer for the integration of high Tc superconducing (HTS) films with metallic substrates can be constructed by forming a layer of a doped cerium oxide interposed between the HTS film and the metallic substrate. The inventors have found that such buffer layers overcome the difficulties in multiple buffer layer fabrication, and also mitigate the lattice expansion and lattice mismatch problems seen when using pure metal oxides or stabilized zirconia-based oxides.

The present invention broadly relates to new buffer layers adapted to mediate property differences between metallic substrates and HTS films so that HTS films can be used in apparatus such as magnetic, electromagnets, magnetic sensors, gyroscopes, inductors, power storage devices, or other electronic or electromechanical apparatus. The buffer layers comprise a doped cerium oxide layer grown on an atomically ordered metallic substrate upon which an HTS film can be grown.

The present invention also broadly relates to a method for constructing metallic substrate-HTS devices including the step of providing a metallically ordered metallic substrate, depositing on a surface of the substrate a doped cerium oxide, biaxially textured, buffer layer and forming on the buffer layer an HTS film.

Suitable metals for use in this invention include, without limitation, any metal on which the buffer layer can be formed. Preferably, any metal capable of biaxial conditioning. Exemplary examples include the Group 13, 3A or IIIA metals (Al, Ga, In, and Tl), the Group VIII and the noble metals (Fe, Co, Ni, Cu, Ru, Rh, Pd, Ag, Os, Ir. Pt, and Au), Group 6, or 6B or VIB metals (Cr, Mo and W), mixtures or combinations thereof and alloys thereof, or the like. Preferred metals include Ni, Fe, Ag, Au, Pt, Cu, Al, iron alloys, nickel alloys, mixtures or combinations thereof or the like. Particularly preferred metals includes Ni, Fe, Ag, iron alloys such as stainless steel, nickel alloys, or mixture or combinations thereof.

Suitable materials for use in the buffer layer(s) of this invention include, without limitation, cerium oxide doped with group 2, IIA or 2A metal oxides, transition element oxides, an lathanide metal oxides, actinide metal oxides or mixtures or combinations thereof. Preferred examples are Sm₂O₃, Y₂O₃, Gd₂O₃, Pr₂O₃, CaO, SrO, or mixtures or combinations thereof. The particularly preferred dopants is Sm oxide, where the Sm concentration from about 0.01 to 0.35 (about 1% to about 35%). The oxides can also be doped into stabilized zirconia based oxides to improve the buffer film quality, i.e., doped cerium oxide can be co-formed with zirconia. Some elements such as La may not be successful dopants for the single buffer layer purpose. As described in U.S. Pat. Pub. No. 2002/0041973, La doped CeO₂ showed good matching with YBCO, but better matching with nickel and crack resistant properties have not been shown. As a result, La-doped CeO₂ buffer layer thickness is inferior or equal to 100 nm, and a lower buffer layer is required for YBCO growth on nickel.

Suitable high Tc superconducting materials for use in this invention include, without limitation, LaCu oxides, LaBaCu oxides, LaSrCu oxides, YbaCu oxides, BiSrCaCu oxides, TlBaCaCu oxides, other high Tc superconducting materials or mixtures or combinations thereof. Exemplary examples include La₂₋ₓBaₓCuO₄, La₂₋ₓSrₓCuO₄, La₂₋ₓSrₓCaCuO₄, YBa₂Cu₃O_{7-δ}, Bi₂Sr₂Ca₂Cu₃O₁₀, Bi₂Sr₂Ca—Cu₂O₈, Bi₂Sr₂Ca₂Ca₃O₈, Tl₂Ba₂Ca₂Cu₃O₁₀, or mixtures or combinations thereof. Preferred HTS includes YBa₂Cu₃O_{7-δ}, La₂₋ₓSrₓCaCuO₄, Bi₂Sr₂Ca₂Ca₃O₈, Tl₂Ba₂Ca₂Cu₃O₁₀, or mixtures or combinations thereof.

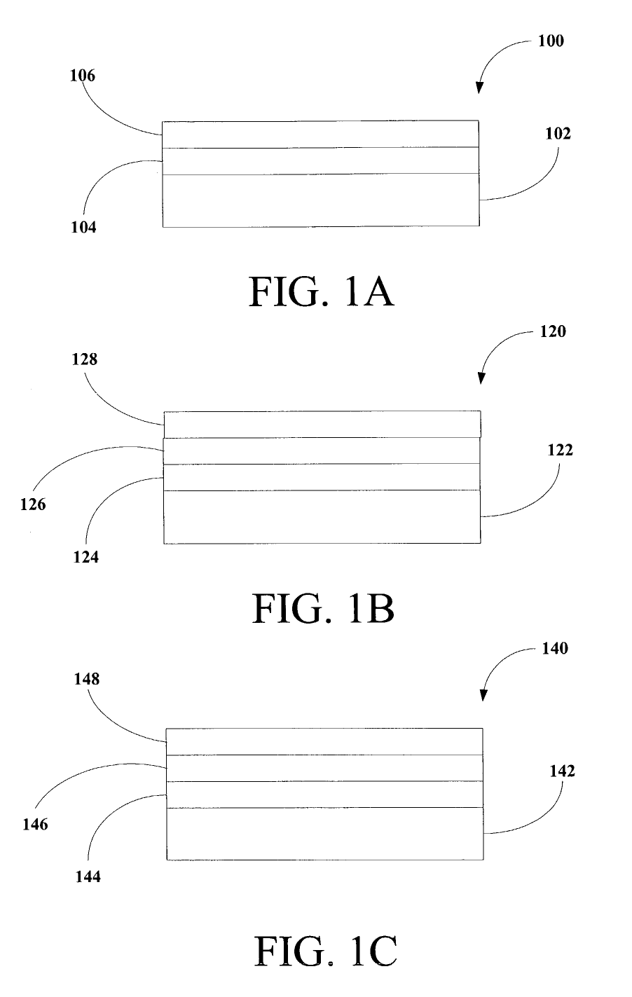

Referring now to FIG. 1A, a layered structure or construct of this invention, generally 100, the construct 100 includes a metallic layer or substrate 102, a buffer layer 104 formed thereon and a HTS layer 106 formed on the buffer layer, where the buffer layer acts as a mediator between the metal lattice of the metallic layer and the HTS lattice improving the match between the thermal expansion coefficients and lattice parameters of the metallic layer and the HTS layer. One preferred apparatus, structure or construct comprises an atomically ordered nickel layer or substrate, a doped cerium oxide (CeO₂) middle buffer layer and a superconducting top layer. It should be understood that the description of a preferred embodiment does not limit the scope of the buffer layer and forming method disclosed herein.

For example, a construct of this invention can be formed form a nickel foil substrate having a thickness of 0.002 inch treated to expose an atomically ordered surface by roll-texturing as described by A. Goyal el al “High critical current density superconducting tapes by epitaxial deposition of YBa₂Cu₃Oₓ, thick films on biaxially textured metals” 69(12) Appl. Phys. Lett. 1795 (1996) upon which a buffer layer of this invention is deposited followed by HTS film formation on the buffer layer. Other than pure nickel, the metallic substrate can be an alloy of nickel, silver, stainless steel or other biaxially textured metal alloys or mixtures or combinations thereof. In addition, single crystalline forms of the above noted substrate materials can be used as well.

In the integration of a superconducting film such as a YBCO film with a metallic Ni substrate, a doped cerium oxide buffer layer is first formed or grown on the Ni substrate. The buffer layer can be formed or grown on the metallic substrate by such techniques as pulsed laser deposition (PLD), sputtering, physical vapor deposition, metal organic chemical vapor deposition (MOCVD), metal organic deposition (MOD) or any other technique for forming layers of material on a substrate or mixtures or combinations thereof. For example, Sm-doped CeO₂ can be formed on the metallic substrate, where the cerium oxide is doped with Sm at concentrations from about 0.01 to about 0.35 (about 1% to about 35%).

The buffer interposed between the metallic substrate and the HTS film is not limited to be a single layer, but can comprise multiple layers to improve the buffer layer quality. The multi-layers can all be a doped oxide or a combination of a doped oxide and an undoped oxides or zirconia based oxide layers or the like. The doping level can be uniform or non-uniform through out the buffer layer, including graded doping distributed in single buffer or multilayer buffer structures or constructs.

Referring now to FIG. 1B, a layered structure or construct of this invention, generally 120, the construct 120 includes a metallic layer or substrate 122, a first buffer layer 124 formed thereon, a second buffer layer 126 formed on the first buffer layer and a HTS layer 128 formed on the second buffer layer, where the buffer layers act as a mediator between the metal lattice of the metallic layer and the HTS lattice improving the match between the thermal expansion coefficients and lattice parameters of the metallic layer and the HTS layer.

Referring now to FIG. 1C, a layered structure or construct of this invention, generally 140, the construct 140 includes a metallic layer or substrate 142, a first buffer layer 144 formed thereon comprising a doped cerium oxide material, a second buffer layer 146 formed on the first buffer layer comprising a doped cerium oxide material co-formed with stabilized zirconia and a HTS layer 148 formed on the second buffer layer, where the buffer layers act as a mediator between the metal lattice of the metallic layer and the HTS lattice improving the match between the thermal expansion coefficients and lattice parameters of the metallic layer and the HTS layer.

The addition of a dopant to a CeO₂ buffer layer allows for oriented buffer layer growth with reduced cracking or without cracking generally seen in undoped CeO₂ layers that are deposited thicker than about 10 nm. The doped buffer layer can be grown using techniques such as PLD, to film thicknesses from about 10 nm (0.01 μm) to greater than about 2000 nm (2 μm). As shown and described in the Experimental Section Sm doped cerium oxide buffer layers can be grown on metal substrates, where the buffer layer show no cracks.

### Experimental Section

In this Experimental Section illustrative examples of the fabrication of multilayered structures having a metallic base and a HTS top layer are demonstrated.

Preparation of Atomically Textured Metallic Substrates

The new constructs of this invention where formed on a metallic substrate of the prior art. Thus, atomically textured Ni substrates were formed by the progressive deformation rolling and high temperature annealing of nickel as described in A. Goyal el al “High critical current density superconducting tapes by epitaxial deposition of YBa₂Cu₃Oₓ thick films on biaxially textured metals” 69(12) Appl. Phys. Lett. 1795 (1996). The substrates were obtained from EURUS Corp.

General Buffer Layer Fabrication

Pulsed laser deposition was used for deposing a thin film deposition of Sm-doped CeO₂ having a target composition. Such target compositions were formed by sintering CeO₂ and Sm₂O₃ oxide powders at a composition ratio that would yield a film have a nominal composition given by Sm_{0.2}Ce_{0.8}O₂. The Sm—CeO₂ buffer layer films were deposited on the textured nickel substrates using a KrF (λ=248 nm) excimer laser with pulse energy between about 300 and about 800 mJ. A forming gas comprising 4% hydrogen in argon (4% H₂/96% Ar) was introduced into a vacuum chamber at a pressure between about 10 m Torr and about 1 Torr during buffer film deposition to minimize/avoid the formation of NiO. The deposition temperature was varied between 500° C. and about 800° C.

Analysis Used For Film Characterization

The appearance and composition of deposited films were characterized using scanning electron microscopy (SEM) and energy dispersive spectroscopy (EDS). The crystalline quality of the films was examined by XRD θ-2θ scans and XRD pole figure analysis. Electron backscatter diffraction (EBSD) was also used for the film analysis.

### EXAMPLE 1

This example illustrates the deposition of a Sm doped cerium oxide layer on an atomically ordered nickel substrate.

SmₓCe₁₋ₓO₂ (SDC) films with x=0.2, were deposited by PLD on atomically textured nickel substrates. The films were generally crystalline over the range of deposition temperatures (about 500 to about 800° C.) when grown in an atmosphere of 500 mtorr forming gas pressure. However, good (100) film orientation ((100) designates the crystal plane normal to the surface) was obtained for Sm—CeO₂ film growth in the temperature range between about 600° C. and about 700° C. Deposition at about 650° C. under varying forming gas pressures between about 500 and about 50 mtorr showed increasing film crystallinity with decreasing forming gas pressure

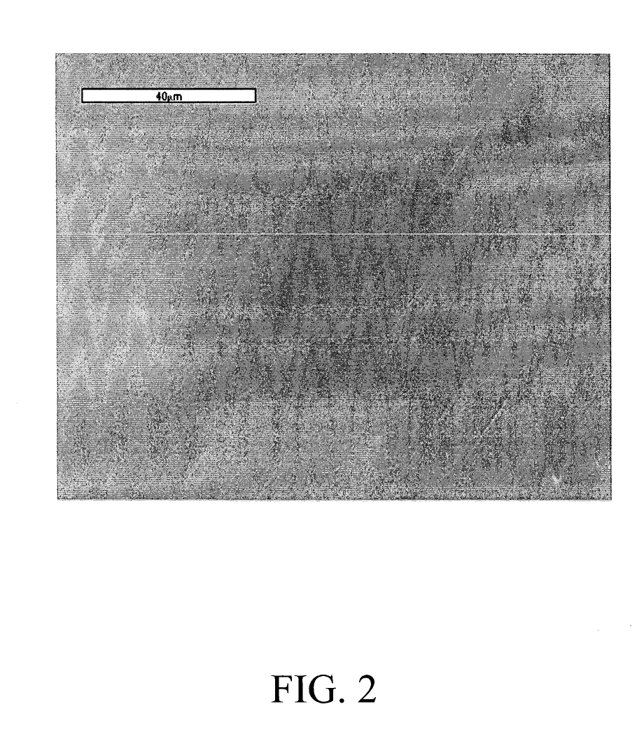

Looking at FIG. 2, an SEM microgram of the SDC film showed a continuous and generally smooth film surface with some surface stripes revealing the rolling marks of the nickel substrate. Cracks, which usually are present in pure CeO₂ buffer layer films thicker than about 5 to about 10 nm, are not found in the SDC films. In addition, as compared with CeO₂, the SDC buffer layer is not required to be very thin (to mitigate cracking), so that the fabrication difficulty is reduced. These crack-free SDC buffer layers are ideally suited for the preparation of new multilayered structures integrating HTS films such as YBCO films with metallic substrates such as atomically ordered roll-textured nickel for ultimate use as HTS thick film wires, tapes, disk surfaces, HTS patterned metallic surfaces or the like.

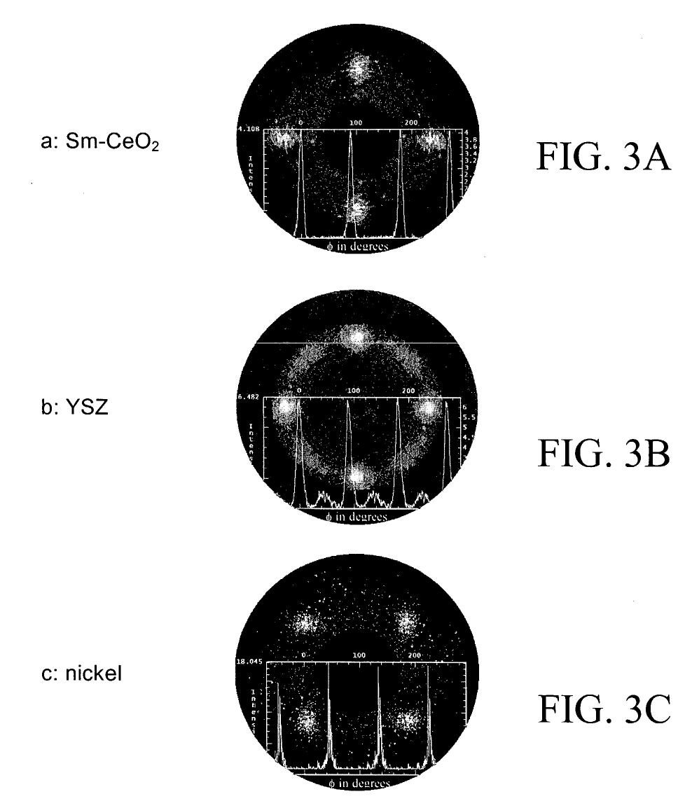

Looking at FIGS. 3A-C, the XRD pole analyses of the (111) peaks of a SDC film and a YSZ film deposited on roll-textured nickel, as well as the XRD of the nickel substrare, are shown, respectfully. The YSZ film exhibit two distinct oriented crystalline domains, which is not good for subsequent YBCO film growth; while the SDC film exhibits only one domain. An φ-scan analysis of Ni (111) reflection indicates a FWHM of about 9° for the atomically textured nickel substrate as shown in FIG. 3C. SDC films deposited at temperatures between about 600° C. and about 700° C. showed good in-plane alignment. The SDC film of Example 1, which was deposited at a forming gas pressure of about 50 mtorr and a temperature of about 650° C., had a φ-scan FWHM of 9°, a value similar to that of the nickel substrate. The a-b atomic alignment of SDC film was rotated 45° relative to the substrate atomic structure as indicated by the pole figure analysis shown in FIG. 3A. This rotation is due to the ˜\sqrt{2} lattice parameter difference (a_{SDC}=5.41 Å; a_{Ni}=3.52 Å) between the SDC film and the substrate.

### EXAMPLE 2

This example illustrates the deposition of an YBCO thin film on the Sm doped cerium oxide layer/atomically ordered nickel substrate construct of Example 1.

YBCO thin films were grown on the Sm-doped CeO₂ buffer layer/roll-textured nickel (SDC/RTNi) sample of Example 1 using a number of oxide growth techniques including PLD. As an example, a YBCO thin film was grown on the Sm-doped CeO₂ buffer layer of a construct of Example 1 at a temperature of about 780° C. with a laser having pulse energies of 540 mJ and pulse frequency of 7 Hz for 10 minutes. The deposition was performed in an oxygen ambient atmosphere having a pressure of about 300 mtorr. The sample chamber was filled with oxygen after deposition to increase oxygen concentration in the YBCO thin film.

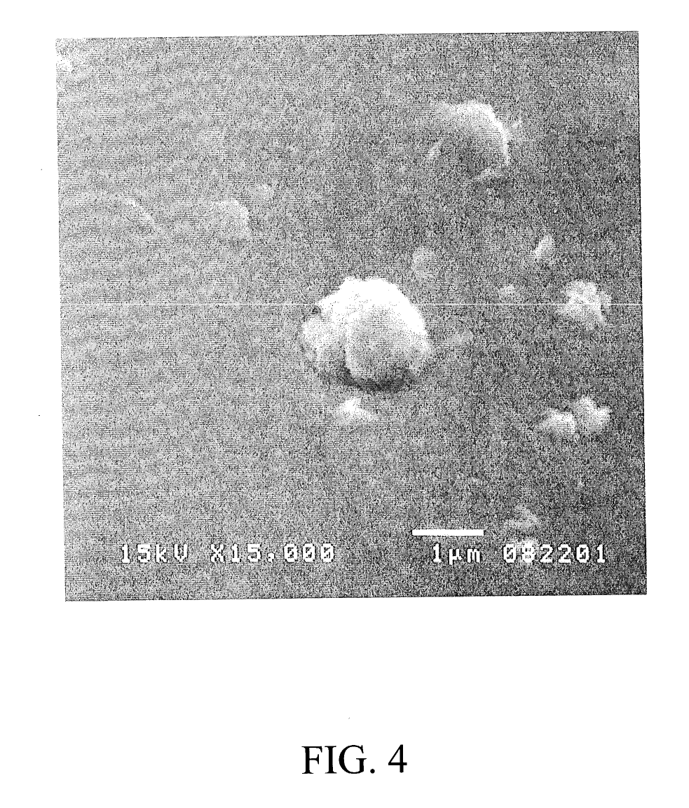

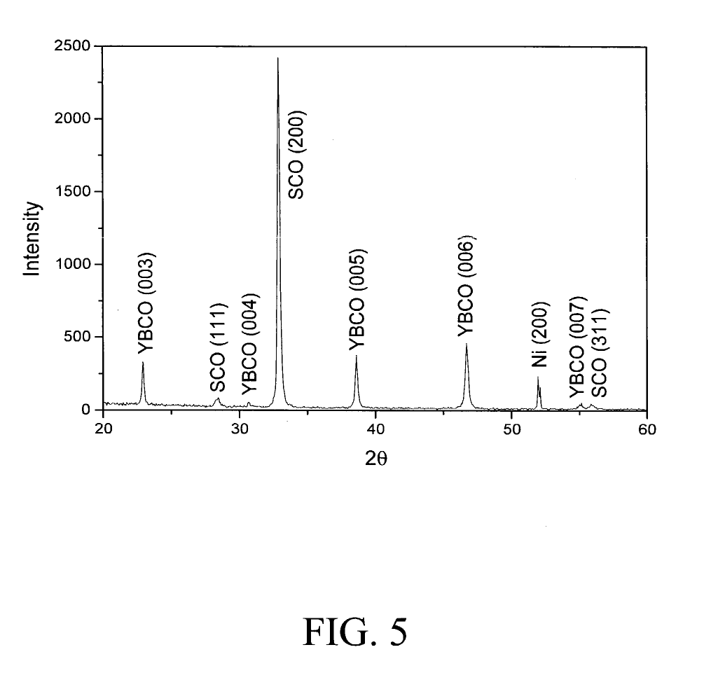

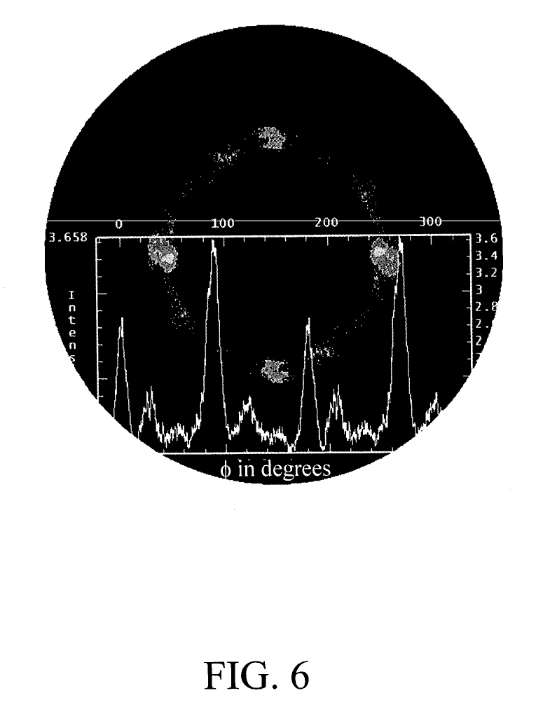

Looking now at FIG. 4, an SEM microgram of the YBCO/SDC/RTNi sample, which indicates a smooth YBCO surface with some micron-sized particles (not unusual for PLD deposited YBCO films). Looking now at FIG. 5, the XRD θ-2θ scan of the sample is shown and indicates the buffer layer is principally (100) oriented, while the YBCO film is (001) oriented. Looking at FIG. 6, the XRD pole figure and φ-scan polots of the YBCO thin film are shown. The φ-scan of YBCO (103) reflection exhibits a FWHM of ˜13°. Jc of 3×10⁴A/cm² was obtained for the YBCO film, which can be improved by improving or optimizing process conditions.

### EXAMPLE 3

This example illustrates the deposition of a Sm doped cerium oxide layer on a single crystalline nickel substrate followed by the deposition of a YBCO film.

A Sm—CeO₂ buffer layer was deposited by PLD on a single crystalline nickel substrate (versus atomically textured nickel foil) followed by YBCO deposition by PLD. The deposition parameters were as typically described earlier.

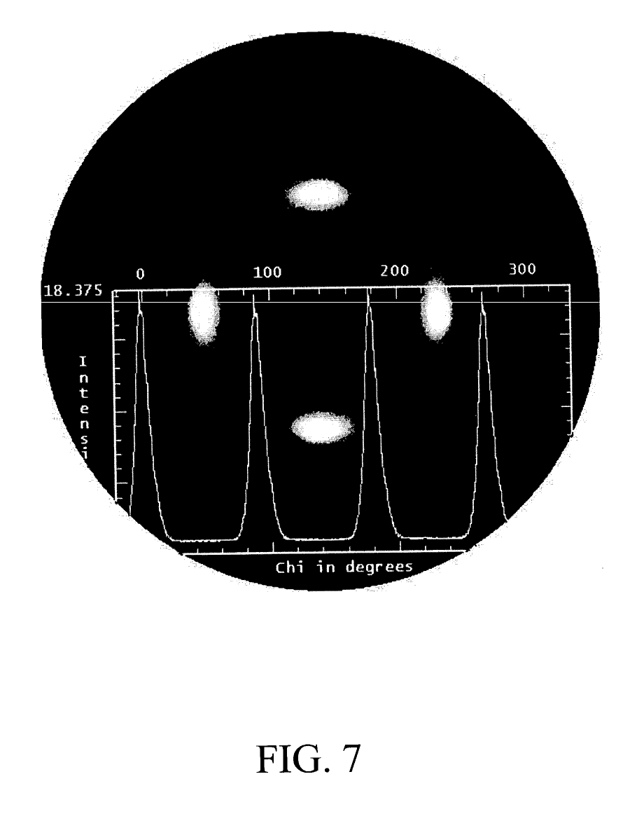

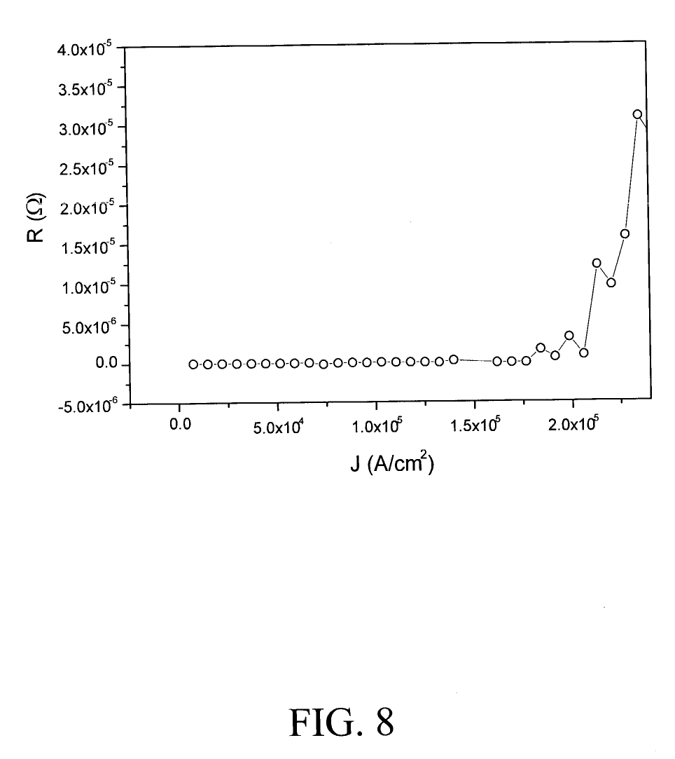

Referring now at FIG. 7, the XRD pole figure and φ-scan of the YBCO thin film are shown. Four strong and smooth peaks were observed in the pole figure and φ-scan analyses. The φ-scan of YBCO (103) showed a FWHM of ˜10°, better than the YBCO deposited on roll-textured nickel by PLD. Referring now at FIG. 8, the J_{C} test results for the sample of this example are shown.

### EXAMPLE 4

This example illustrates the deposition of a Sm doped cerium oxide layer on an atomically oriented nickel substrate followed by the deposition of a YBCO film using MOCVD.

An Sm—CeO₂ article was prepared as in Example 1 but was followed by the deposition of a YBCO film onto the Sm—CeO₂ by photo-assisted MOCVD, a thin film deposition technique different from PLD. The photo-assisted MOCVD process for YBCO and other oxide film growth processes have been previously described in A. Ignatiev, P. C. Chou, Q. Zhong, X. Zhang and Y. M. Chen Applied Superconductivity 4 (1998) 455, and in Y. M. Chen, N. J. Wu and A. Ignatiev MRS Symposium Proceeding 596 (1999) 49. A vacuum MOCVD reactor is used and is energized by tungsten-halogen lamps. The lamps supply not only thermal energy, but also allow for photo-stimulation of chemical and physical processes involved in the MOCVD reaction.

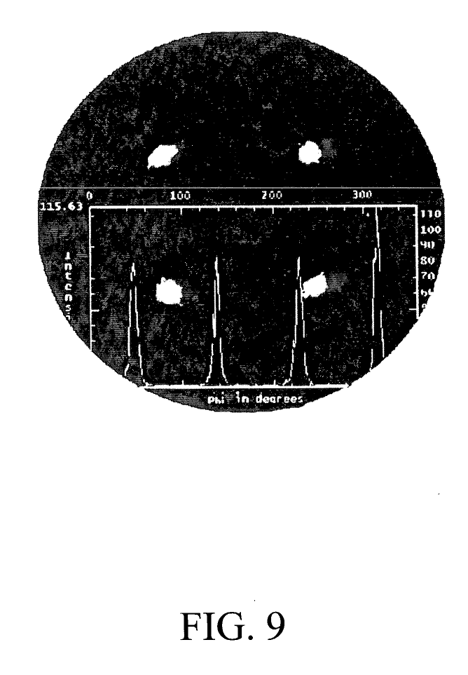

A 1.51 μm thick YBCO film was deposited on top of the SDC buffer layer. Referring now at FIG. 9, the XRD pole figure and φ-scan of the YBCO film showed a YBCO (103) peak and a FWHM ˜10° in the φ-scan indicating similar in-plane ordering to that of the substrate and the buffer layer with the resulting YBCO film as good as the film deposited on a SDC—buffer layer single crystalline nickel substrate by PLD. The YBCO film is c-oriented and the SDC buffer layer is (100) oriented.

### EXAMPLE 5

This example illustrates the deposition of heterostructures of Yttria stabilized zirconia (YSZ) and a Sm doped cerium oxide (SDC) layers on an atomically oriented nickel substrate.

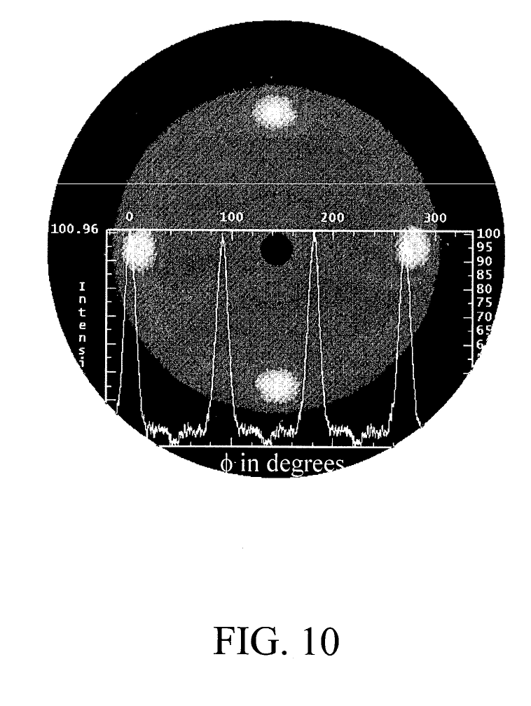

Heterostructures of YSZ/SmₓCe₁₋ₓO₂ (100) were also deposited on roll-textured Ni. The SDC layer was deposited at a temperature of about 650° C. and a forming gas pressure of about 50 mtorr. The YSZ layer was then deposited at a temperature of about 830° C. in forming gas. Referring now to FIG. 10, the YSZ layer showed an improved in-plane alignment over the SDC film with a φ-scan FWHM of ˜8°. As a comparison, the φ-scan of a YSZ film that was deposited directly on Ni showed a two domain structure, which is detrimental to the development of atomically ordered YBCO layer that are important for high superconducting quality HTS tape applications as shown in FIG. 2B.

The example results presented here are primarily and are presented to demonstrate the preferred structures and methods for making and using them. The foregoing disclosure and description and examples are illustrative and explanatory, and are amenable to various changes, augmentations, and alterations without departing from the scope and content of the invention. Ordinary artisans should recognize that the final commercial methodology and structure may depart in some details from the examples, but will include the fundamental aspects of this invention.

### REFERENCES

U.S. Pat. No. 6,106,615 to Goyal et al.; U.S. Pat. No. 5,898,020 to Goyal et al.; U.S. Pat. No. 5,432,151 to Russo et al.; U.S. Pat. No. 6,077,344 to Shoup et al.; U.S. Pat. No. 5,972,847 to Feenstra et al.; U.S. Pat No. 6,150,034 to Paranthaman et al.; U.S. Pat. No. 6,156,376 to Paranthaman et al.; and U.S. Patent Application Pub. No. 2002/0041973 to Belouet., incorporated herein by reference.

Journal Articles: Y. Iijima et al. “Structural and Transport-Properties of Biaxially Aligned YBa₂Cu₃O₇₋ₓ Films on Polycrystalline Ni-Based Alloy With Ion-Beam-Modified Buffer Layers” 74(3) J. Appl. Phys 1905-1911 (1993); X. D. Wu et al. “Preparation of High-Quality YBa₂Cu₃O_{7-Delta} Thick-Films on Flexible Ni-Based Alloy Substrates With Textured Buffer Layers” 5(2) IEEE. T. Appl. Supercon. 2001-2006 (1995); K. Hasegawa et al., “Biaxially aligned YBCO film tapes fabricated by all pulsed laser deposition” 4(10-11) Applied Superconductivity 487-493 (1996); C. H. Hur et al., “Fabrication of YBa₂Cu₃O₇₋ₓ superconducting film with CeO₂/BaTiO double buffer layer” 398-399 Thin Solid Films 444-447 (2001); F. A. List et at., “High J(c) YBCO films on biaxially textured Ni with oxide buffer layers deposited using electron beam evaporation and sputtering” 302(1) Physica C 87-92 (1998); A. Ignatiev et al. “Photo-assisted MOCVD fabrication of YBCO thick films and buffer layers on flexible metal substrates for wire applications”, 12(29-31) International Journal of Modern Physics B 3162-3173 (1998); M. Jin et al., “Biaxial texturing of Cu sheets and fabrication of ZrO₂ buffer layer for YBCOHTS films” 334(3-4) Physica C 243-248 (2000); and E. Celik et al., “CeO₂ buffer layers for YBCO: Growth and processing via sol-gel technique” 9(2) IEEE Transactions on Applied Superconductivity 2264-2267 Part 2 (1999), incorporated herein by reference.

All references cited herein are incorporated herein by reference for all purposes allowed by law. While this invention has been described fully and completely, it should be understood that, within the scope of the appended claims, the invention may be practiced otherwise than as specifically described. Although the invention has been disclosed with reference to its preferred embodiments, from reading this description those of skill in the art may appreciate changes and modification that may be made which do not depart from the scope and spirit of the invention as described above and claimed hereafter.

We claim:

1. An apparatus comprising a metallic substrate, a high Tc superconductor (HTS) layer and at least one crack resistant, doped metal oxide buffer layer interposed therebetween, where the buffer layer is adapted to act as an anti-diffusion barrier between the substrate and HTS layer and as a lattice transition zone between a lattice of the metal substrate and a lattice of the HTS layer.

2. The apparatus of claim 1, wherein the metallic substrate is any metal capable of biaxial conditioning.

3. The apparatus of claim 1, wherein the metallic substrate is selected from the group consisting of Group 13, 3A or IIIA metals (Al, Ga, In, and Tl), Group VIII metals, noble metals (Fe, Co, Ni, Cu, Ru, Rh, Pd, Ag, Os, Ir. Pt, and Au), Group 6, or 6B or VIB metals (Cr, Mo and W), alloys thereof and mixtures or combinations thereof.

4. The apparatus of claim 1, wherein the metallic substrate is selected from the group consisting of Ni, Fe, Ag, Au, Pt, Cu, Al, iron alloys, nickel alloys, and mixtures or combinations thereof.

5. The apparatus of claim 1, wherein the metallic substrate is selected from the group consisting of Ni, Fe, Ag, iron alloys, nickel alloys, and mixture or combinations thereof.

6. The apparatus of claim 1, wherein the metal substrate is selected from the group consisting of a atomically textured nickel substrate, single crystalline nickel substrate, and other atomically ordered metallic substrates.

7. The apparatus of claim 1, wherein the buffer layer comprises cerium oxide doped with a group 2, IIA or 2A metal oxide, a transition element oxide, an lathanide metal oxide, actinide metal oxide or mixtures or combinations thereof.

8. The apparatus of claim 1, wherein the buffer layer comprises cerium oxide doped with a metal oxide selected from the group consisting of Sm₂O₃, Y₂O₃, Gd₂O₃, Pr₂O₃, CaO, SrO, and mixtures or combinations thereof.

9. The apparatus of claim 1, wherein the buffer layer comprises cerium oxide doped with Sm oxide at a Sm concentration between about 0.01 to 0.35.

10. The apparatus of claim 7, wherein the doping level is uniform or non-uniform through the buffer layer.

11. The apparatus of claim 7, wherein the doping level is a graded doping distribution.

12. The apparatus of claim 1, wherein the buffer layer comprises a mixed oxide including cerium oxide and at least one oxide selected from the group consisting of a group 2, IIA or 2A metal oxide, a transition element oxide, an lathanide metal oxide, actinide metal oxide and mixtures or combinations thereof doped into or co-formed with a stabilized zirconia based oxide.

13. The apparatus of claim 1, wherein the high Tc superconducting material is selected from the group consisting of LaCu oxides, LaBaCu oxides, LaSrCu oxides, YbaCu oxides, BiSrCaCu oxides, TlBaCaCu oxides, other high Tc superconducting materials and mixtures or combinations thereof.

14. The apparatus of claim 1, wherein the high Tc superconducting material is selected from the group consisting of La₂₋ₓBaₓCuO₄, La₂₋ₓSrₓCuO₄, La₂₋ₓSrₓCaCuO₄, YBa₂Cu₃O_{7-δ}, Bi₂Sr₂Ca₂Cu₃O₁₀, Bi₂Sr₂Ca—Cu₂O₈, Bi₂Sr₂Ca₂Ca₃O₈, Tl₂Ba₂Ca₂Cu₃O₁₀, and

15. The apparatus of claim 1, wherein the high Tc superconducting material is selected from the group consisting of YBa₂Cu₃O_{7-δ}, La₂₋ₓSrₓCaCuO₄, Bi₂Sr₂Ca₂Ca₃O₈, Tl₂Ba₂Ca₂Cu₃O₁₀, and mixtures or combinations thereof.

16. The apparatus of claim 1, further comprising at least one additional buffer layer comprising an undoped oxide or a zirconia based oxide.

17. The apparatus of claim 1, wherein the apparatus is a wire, a tape, a disk surface, or HTS patterned metallic surface.

18. An apparatus comprising a metallic substrate, a high Tc superconductor (HTS) layer, and a plurality of crack resistant, doped metal oxide buffer layers interposed therebetween, where the buffer layers are adapted to act as an anti-diffusion barrier between the substrate and HTS layer and as a lattice transition zone between a lattice of the metal substrate and a lattice of the HTS layer.

19. The apparatus of claim 18, wherein the buffer layer comprises cerium oxide doped with a group 2, IIA or 2A metal oxide, a transition element oxide, an lathanide metal oxide, actinide metal oxide or mixtures or combinations thereof.

20. The apparatus of claim 18, wherein the buffer layer comprises cerium oxide doped with a metal oxide selected from the group consisting of Sm₂O₃, Y₂O₃, Gd₂O₃, Pr₂O₃, CaO, SrO, mixtures or combinations thereof

21. The apparatus of claim 18, wherein the buffer layer comprises cerium oxide doped with Sm oxide at a Sm concentration between about 0.01 to 0.35.

22. The apparatus of claim 19, wherein the doping level is uniform or non-uniform through the buffer layer.

23. The apparatus of claim 19, wherein the doping level is a graded doping distribution.

24. The apparatus of claim 18, wherein the buffer layers comprise a graded layer stacking structure.

25. The apparatus of claim 18, wherein the high Tc superconducting material is selected from the group consisting of La₂₋ₓBaₓCuO₄, La₂₋ₓSrₓCuO₄, La₂₋ₓSrₓCaCuO₄, YBa₂Cu₃O_{7-δ}, Bi₂Sr₂Ca₂Cu₃O₁₀, Bi₂Sr₂Ca—Cu₂O₈, Bi₂Sr₂Ca₂Ca₃O₈, Tl₂Ba₂Ca₂Cu₃O₁₀, and mixtures or combinations thereof.

26. The apparatus of claim 18, wherein the high Tc superconducting material is selected from the group consisting of YBa₂Cu₃O_{7-δ}, La₂₋ₓSrₓCaCuO₄, Bi₂Sr₂Ca₂Ca₃O₈, Tl₂Ba₂Ca₂Cu₃O₁₀, mixtures or combinations thereof.

27. The apparatus of claim 18, further comprising at least one additional buffer layer comprising an undoped oxide or a zirconia based oxide.

28. The apparatus of claim 18, wherein the metallic substrate is selected from the group consisting of Ni, Fe, Ag, iron alloys, nickel alloys, and mixture or combinations thereof.

29. The apparatus of claim 18, wherein the metal substrate is selected from the group consisting of a atomically textured nickel substrate, single crystalline nickel substrate, and other atomically ordered metallic substrates.

30. The apparatus of claim 18, wherein the apparatus is a wire, a tape, a disk surface, or HTS patterned metallic surface.

31. A thick biaxially textured single buffer layer adapted to be interposed between a high Tc superconductor film and an atomically ordered metallic substrate, where the buffer layer is crack resistance and is adapted to act as an anti-diffusion barrier between the substrate and the HTS layer and as a lattice transition zone between a lattice of the metal substrate and a lattice of the HTS layer.

32. The layer of claim 31, having a thickness of greater than 30 nm.

33. The layer of claim 31, wherein the buffer layer comprises cerium oxide doped with a metal oxide selected from the group consisting of Sm₂O₃, Y₂O₃, Gd₂O₃, Pr₂O₃, CaO, SrO, and mixtures or combinations thereof.

34. The layer of claim 31, wherein the buffer layer comprises cerium oxide doped with Sm oxide at a Sm concentration between about 0.01 to 0.35.

35. The layer of claim 33, wherein the doping level is uniform or non-uniform through the buffer layer.

36. The layer of claim 33, wherein the doping level is a graded doping distribution.

37. The layer of claim 31, wherein the buffer layer comprises at least two separate layers in a graded layer stacking structure.

38. The layer of claim 31, where in the layer further comprises at least one additional buffer layer comprising an undoped oxide or a zirconia based oxide.
